(19) United States
(12) Patent Application Publication
(10) Pub. No.: US 2006/0081902 A1
(43) Pub. Date: Apr. 20, 2006

(54) Ferroelectric memory and method of manufacturing the same

(75) Inventors: Akihito Matsumoto, Suwa (JP); Toshiyuki Kamiya, Fujimi (JP); Kenji Yamada, Kuwana (JP); Eiji Natori, Chino (JP); Tomoo Kinoshita, Fujimi (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/252,316

(22) Filed: Oct. 17, 2005

(30) Foreign Application Priority Data
Oct. 19, 2004 (JP) 2004-303720
Aug. 12, 2005 (JP) 2005-234410

(51) Int. Cl. H01L 29/94; H01L 21/8242

(52) U.S. Cl. 257/295; 257/532; 438/3; 438/240; 438/396

(57) ABSTRACT

A method of manufacturing a ferroelectric memory includes: (a) stacking a lower electrode layer, a ferroelectric layer, and an upper electrode layer on a base in that order to form a ferroelectric laminate; (b) patterning the ferroelectric laminate to form a ferroelectric capacitor; (c) forming a first barrier film which covers the ferroelectric capacitor by physical vapor deposition (PVD); and (d) forming a second barrier film which covers the first barrier film by chemical vapor deposition (CVD).

Japanese Patent Application No. 2004-303720, filed on Oct. 19, 2004, and Japanese Patent Application No. 2005-234410, filed on Aug. 12, 2005 are hereby incorporated by reference in their entireties.

### BACKGROUND OF THE INVENTION

The present invention relates to a ferroelectric memory and a method of manufacturing the same. More particularly, the invention relates to a ferroelectric memory in which a capacitor section is covered with a barrier film, and a method of manufacturing the same.

In recent years, a ferroelectric memory has been extensively studied and developed. The ferroelectric memory has a structure in which a ferroelectric layer is formed between a lower electrode layer and an upper electrode layer. A ferroelectric material used for the ferroelectric memory, such as a PZT ferroelectric material which is an oxide containing Pb, Zr, and Ti, may react with reducing agents such as hydrogen and be damaged due to oxygen deficiency. Moreover, the ferroelectric memory may be damaged by the piezoelectric characteristics of the PZT ferroelectric material. As a result, the ferroelectric memory deteriorates in characteristics such as showing a decrease in polarization or an increase in leakage current.

As a method of protecting the ferroelectric memory from reducing agents, JP-A-11-74471 discloses a method of covering the ferroelectric capacitor with a silicon nitride film, for example.

### SUMMARY

A method of manufacturing a ferroelectric memory according to a first aspect of the invention comprises:

(a) stacking a lower electrode layer, a ferroelectric layer, and an upper electrode layer on a base in that order to form a ferroelectric laminate;

(b) patterning the ferroelectric laminate to form a ferroelectric capacitor;

(c) forming a first barrier film which covers the ferroelectric capacitor by physical vapor deposition (PVD); and

(d) forming a second barrier film which covers the first barrier film by chemical vapor deposition (CVD).

A ferroelectric memory according to a second aspect of the invention comprises:

a ferroelectric capacitor including a lower electrode layer, a ferroelectric layer, and an upper electrode layer formed on a base in that order; and

a plurality of barrier films covering the ferroelectric capacitor.

### BRIEF DESCRIPTION OF THE SEVERAL VIEWS OF THE DRAWING

FIG. 1 is a cross-sectional diagram schematically showing a method of manufacturing a ferroelectric memory according to one embodiment of the invention.

FIG. 2 is a cross-sectional diagram schematically showing a method of manufacturing a ferroelectric memory according to one embodiment of the invention.

FIG. 3 is a cross-sectional diagram schematically showing a method of manufacturing a ferroelectric memory according to one embodiment of the invention.

FIG. 4 is a cross-sectional diagram schematically showing a method of manufacturing a ferroelectric memory according to one embodiment of the invention.

FIG. 5 is a cross-sectional diagram schematically showing a method of manufacturing a ferroelectric memory according to one embodiment of the invention.

FIG. 6 is a cross-sectional diagram schematically showing the ferroelectric memory according to one embodiment of the invention.

FIG. 7 is a graph showing the remanent polarization of the ferroelectric memory according to one embodiment of the invention.

FIG. 8 is a cross-sectional diagram schematically showing a capacitor section of a ferroelectric memory according to a first modification.

FIG. 9 is a cross-sectional diagram schematically showing the ferroelectric memory according to the first modification.

FIG. 10 is a graph showing the amount of oxygen released from a barrier film.

FIG. 11 is a graph showing the remanent polarization of a ferroelectric memory according to a second modification.

FIG. 12 is a cross-sectional diagram schematically showing a method of manufacturing a ferroelectric memory according to a third modification.

FIG. 13 is a cross-sectional diagram schematically showing the ferroelectric memory according to the third modification.

### DETAILED DESCRIPTION OF THE EMBODIMENT

The invention may provide a ferroelectric memory which deteriorates in characteristics to only a small extent during and after manufacture and exhibits high reliability, and a method of manufacturing the same.

A method of manufacturing a ferroelectric memory, according to one embodiment of the invention, includes:

(a) stacking a lower electrode layer, a ferroelectric layer, and an upper electrode layer on a base in that order to form a ferroelectric laminate;

(b) patterning the ferroelectric laminate to form a ferroelectric capacitor;

(c) forming a first barrier film which covers the ferroelectric capacitor by physical vapor deposition (PVD); and

(d) forming a second barrier film which covers the first barrier film by chemical vapor deposition (CVD).

According to one embodiment of the invention, since the first barrier film is formed by PVD in the step (c) before forming the second barrier film by CVD in the step (d), damage to the ferroelectric layer due to reducing agents such as hydrogen produced in the step (d) can be reduced.

With the method of manufacturing a ferroelectric memory according to this embodiment,

the chemical vapor deposition may be atomic layer chemical vapor deposition (ALCVD).

The second barrier film having excellent coverage characteristics can be formed by applying ALCVD in the step (d).

With the method of manufacturing a ferroelectric memory according to this embodiment, the physical vapor deposition may be sputtering.

With the method of manufacturing a ferroelectric memory, according to an embodiment of the invention, the step (c) may include patterning the first barrier film into a specific shape after depositing the first barrier film.

According to one embodiment of the invention, since only one barrier film is formed in the region of the ferroelectric memory other than a specific region, etching for forming a contact hole or the like can be easily controlled in comparison with the case where two barrier films are stacked.

With the method of manufacturing a ferroelectric memory according to this embodiment, the first barrier film and the second barrier film may be nonconductive films.

With the method of manufacturing a ferroelectric memory according to this embodiment, the nonconductive film may include aluminum oxide or titanium oxide.

The method of manufacturing a ferroelectric memory according to this embodiment may include forming a third barrier film which covers the ferroelectric capacitor by chemical vapor deposition between the steps (b) and (c), and

the step (c) may include forming the first barrier film which covers the third barrier film by physical vapor deposition.

With the method of manufacturing a ferroelectric memory according to this embodiment, the step (c) may include forming the first barrier film while supplying oxygen gas.

A ferroelectric memory according to one embodiment of the invention includes:

a ferroelectric capacitor including a lower electrode layer, a ferroelectric layer, and an upper electrode layer formed on a base in that order; and

a plurality of barrier films covering the ferroelectric capacitor.

With the ferroelectric memory according to this embodiment, the barrier films may differ in density.

With the ferroelectric memory according to this embodiment, the barrier films may include:

a first barrier film formed to cover the ferroelectric capacitor; and

a second barrier film formed to cover the first barrier film.

With the ferroelectric memory according to this embodiment, the first barrier film may have a density lower than a density of the second barrier film.

With the ferroelectric memory according to this embodiment, the barrier films may include a third barrier film formed to cover the ferroelectric capacitor, and the first barrier film may be formed to cover the third barrier film.

With the ferroelectric memory according to this embodiment, the third barrier film may have a thickness smaller than thicknesses of the first barrier film and the second barrier film.

With the ferroelectric memory according to this embodiment, the third barrier film may have a density higher than a density of the first barrier film.

With the ferroelectric memory according to this embodiment, the first barrier film may have oxygen supply capability.

The embodiments of the invention are described below with reference to the drawings.

### 1. Method of Manufacturing Ferroelectric Memory

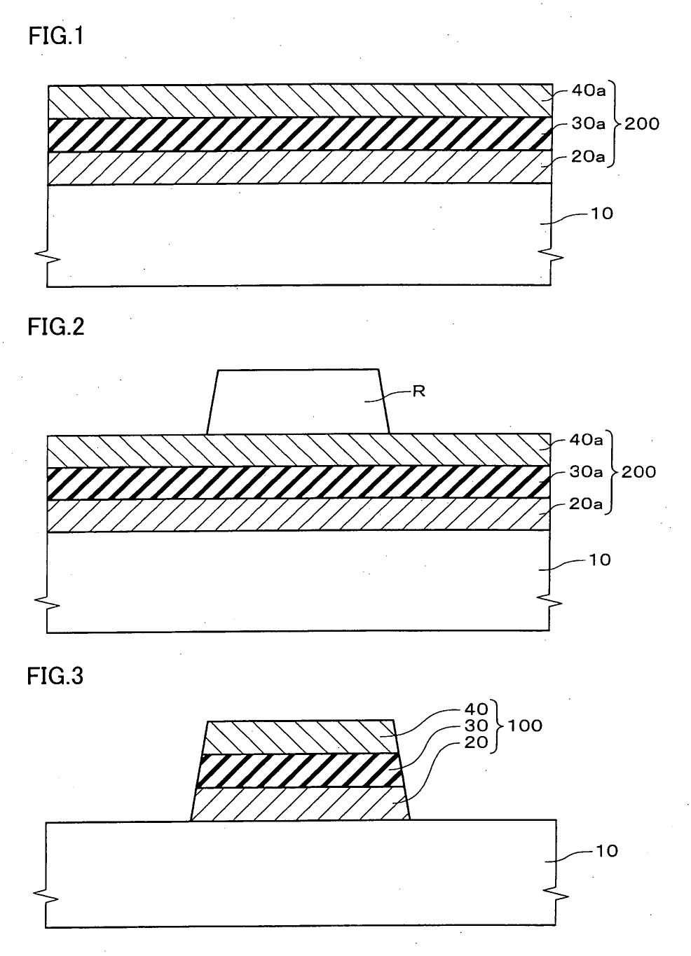

FIGS. 1 to 5 are cross-sectional diagrams schematically showing a method of manufacturing a ferroelectric memory according to one embodiment of the invention.

An example of the method of manufacturing a ferroelectric memory is described below.

(1) As shown in FIG. 1, a base 10 is provided. The base 10 may include a silicon substrate and a silicon oxide film formed on the silicon substrate, for example. A functional device such as a transistor may be formed on the base 10.

A conductive layer 20a for forming a lower electrode (hereinafter called “lower electrode layer 20a”), a layer 30a for forming a ferroelectric layer (hereinafter called “ferroelectric layer 30a”), and a conductive layer 40a for forming an upper electrode (hereinafter called “upper electrode layer 40a”) are stacked on the base 10 in that order to form a ferroelectric laminate 200.

The lower electrode layer 20a is not particularly limited insofar as the lower electrode layer 20a can function as an electrode of a ferroelectric capacitor. As the material for the lower electrode layer 20a, a noble metal such as Pt or Ir, a noble metal oxide (e.g. IrOₓ), an SrRu complex oxide, or the like may be used. The lower electrode layer 20a may be a single layer of the above-mentioned material, or may have a multilayer structure in which layers of different materials are stacked. As the deposition method for the lower electrode layer 20a, a known method such as sputtering, vacuum deposition, or CVD may be used.

The ferroelectric layer 30a may be formed by using a PZT ferroelectric which is an oxide including Pb, Zr, and Ti as the constituent elements. Or, Pb(Zr, Ti, Nb)O₃ (PZTN) in which the Ti site is doped with Nb may be applied. It should be noted that the material for the ferroelectric layer 30a is not limited to these materials. For example, an SBT ferroelectric, BST ferroelectric, BIT ferroelectric, or BLT ferroelectric may be used. As the deposition method for the ferroelectric layer 30a, a solution coating method (including a sol-gel method, a metal organic decomposition (MOD) method, and the like), a sputtering method, a chemical vapor deposition (CVD) method, and the like can be given.

The upper electrode layer 40 may be deposited by using a material and a method the same as the material and the method for the lower electrode layer 20a.

(2) The ferroelectric laminate 200 is patterned to form a ferroelectric capacitor 100. As shown in FIG. 2, a resist layer R is formed on the ferroelectric laminate 200 by using photolithographic technology.

The ferroelectric laminate 200 is then etched in the area in which the ferroelectric laminate 200 is not covered with the resist layer R to form the ferroelectric capacitor 100, as shown in FIG. 3. The etching method may be appropriately selected according to the material and the film thickness. As examples of the etching method, a dry etching method and a wet etching method can be given.

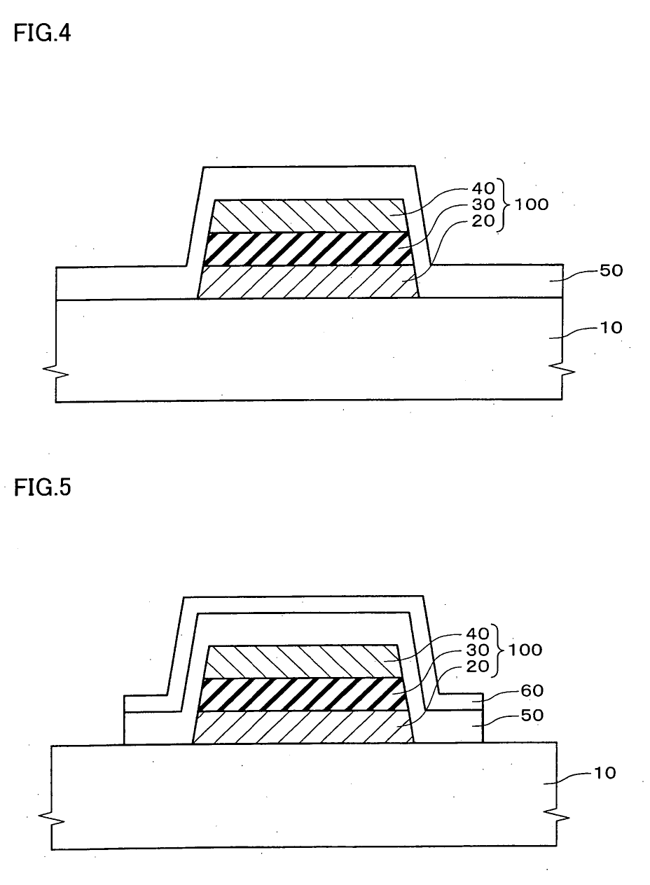

(3) As shown in FIG. 4, a first barrier film 50 is formed. The first barrier film 50 covers the ferroelectric capacitor 100. As the material for the first barrier film 50, aluminum oxide may be used, for example. However, the material for the first barrier film 50 is not limited to aluminum oxide insofar as the material can protect the ferroelectric layer 30 from reducing agents such as hydrogen. For example, silicon oxide, titanium nitride, titanium oxide, aluminum oxide, silicon nitride, or the like may be used. As the deposition method for the first barrier film 50, physical vapor deposition (PVD) such as sputtering or vacuum deposition is applied.

(4) A second barrier film 60 is formed. The second barrier film 60 is formed on the first barrier film 50. As the material for the second barrier film 60, a material the same as the material for the first barrier film 50 may be used. As the deposition method for the second barrier film 60, atomic layer chemical vapor deposition (ALCVD) is applied.

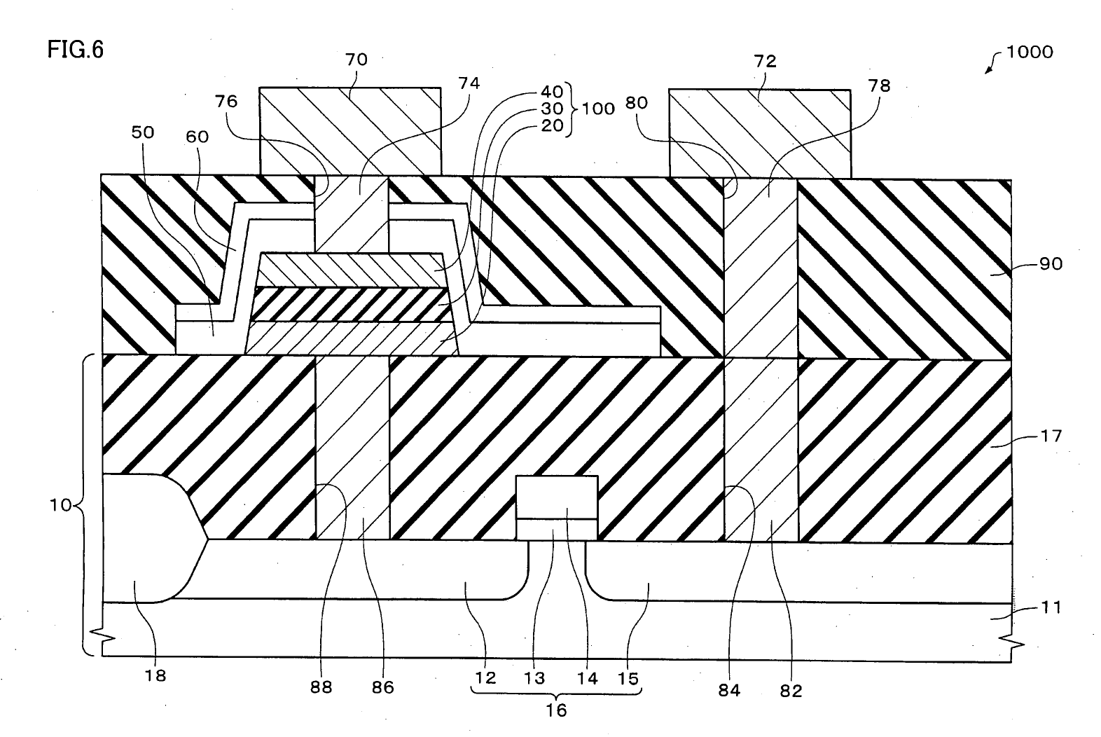

As shown in FIG. 5, the first barrier film 50 and the second barrier film 60 are patterned.

The features of the method of manufacturing a ferroelectric memory according to one embodiment of the invention are as follows.

The method of manufacturing a ferroelectric memory according to one embodiment of the invention includes the step of forming the first barrier film 50 by physical vapor deposition (PVD) and the step of forming the second barrier film 60 by chemical vapor deposition (CVD).

A related-art ferroelectric memory includes only one barrier film formed by PVD or CVD. Since a barrier film formed by PVD has inferior coverage properties in comparison with a barrier film formed by CVD, the barrier film formed by PVD cannot sufficiently protect the ferroelectric capacitor from reducing agents such as hydrogen. On the other hand, since a barrier film formed by CVD has a large film stress in comparison with a barrier film formed by PVD, the ferroelectric capacitor is damaged to a large extent due to the piezoelectric characteristics of the ferroelectric material. A barrier film formed by CVD produces reducing agents such as hydrogen due to a chemical reaction occurring in the deposition step, so that the ferroelectric layer 30 may be damaged. The above-described CVD characteristics more significantly occur when applying ALCVD.

Therefore, the exposed area of the ferroelectric layer 30 is covered by forming the first barrier film 50 by PVD before forming the second barrier film 60 by CVD, so that the ferroelectric capacitor 100 can be protected from reducing agents produced in the manufacturing process. Therefore, damage to the ferroelectric layer 30 can be reduced. Moreover, since the first barrier film 50 has a small film stress in comparison with the second barrier film 60, damage caused by the piezoelectric characteristics of the ferroelectric material can be reduced.

In the ferroelectric memory according to one embodiment of the invention, excellent coverage can be obtained by forming the second barrier film 60 on the first barrier film 50 in comparison with the case of forming only the first barrier film 50. In particular, more excellent coverage can be realized by forming the second barrier film 60 by ALCVD. Therefore, the ferroelectric layer 30 can be prevented from being damaged by reducing agents such as hydrogen after manufacturing the ferroelectric memory. As described above, the ferroelectric memory according to one embodiment of the invention can be prevented from deteriorating in characteristics during and after manufacture.

A heat treatment may be performed in the manufacturing process of a ferroelectric memory 1000 according to one embodiment of the invention. For example, a heat treatment may be performed after deposition of the ferroelectric layer 30a and after the step (4). A drying heat treatment and a cleaning heat treatment are performed after deposition of the ferroelectric layer 30a, for example. The drying heat treatment is performed at 150° C. to 180° C. The drying heat treatment is performed in air using a hot plate or the like. The cleaning heat treatment is performed in air on a hot plate maintained at 300° C. to 350° C. After the deposition and the step (4), post annealing may be performed at 600° C. to 700° C. in an oxygen atmosphere by thermal rapid annealing (RTA) or the like. This enables formation of an excellent interface between the upper electrode layer 40 and the ferroelectric layer 30, and improves the crystallinity of the ferroelectric layer 30.

### 2. Ferroelectric Memory

A ferroelectric memory according to one embodiment of the invention may be manufactured by the above-described manufacturing steps. FIG. 6 is a cross-sectional diagram schematically showing an example of the ferroelectric memory according to one embodiment of the invention.

The ferroelectric memory 1000 includes the ferroelectric capacitor 100 and the base 10. The ferroelectric capacitor 100 includes the lower electrode layer 20 formed on the base 10, the ferroelectric layer 30 formed on the lower electrode layer 20, and the upper electrode layer 40 formed on the ferroelectric layer 30.

The ferroelectric memory 1000 includes a plurality of barrier films formed on the ferroelectric capacitor 100. In more detail, the ferroelectric memory 1000 includes the first barrier film 50 formed to cover the ferroelectric capacitor 100, and the second barrier film 60 formed to cover the first barrier film 50. The first barrier film 50 and the second barrier film 60 differ in density. In more detail, it is preferable that the first barrier film 50 have a density lower than the density of the second barrier film 60. For example, the first barrier film 50 may have a density of 2.7 to 2.8 g/cm³, and the second barrier film 60 may have a density of 3.1 to 3.4 g/cm³. Therefore, since the film stress of the first barrier film 50 applied to the ferroelectric capacitor 100 can be reduced, damage caused by the piezoelectric characteristics can be reduced. The density of the second barrier film 60 can be increased by ALCVD or the like, whereby excellent coverage can be obtained. Therefore, damage to the ferroelectric layer 30 due to reducing agents such as hydrogen can be reduced during or after the manufacture of the ferroelectric memory 100.

The base 10 includes a substrate 11, a transistor 16, a first contact section 86, a second contact section 82, a first insulating layer 17, and an element isolation region 18. The transistor 16 is configured to include a source 12 and a drain 15 formed on the substrate 11, a gate insulating film 13, and a gate 14. The transistor 16 may be formed by using a known method.

Contact holes 88 and 84 are formed in the first insulating layer 17. The first contact section 86 and the second contact section 82 having electric conductivity are formed in the contact holes 88 and 84, respectively. The first contact section 86 and the second contact section 82 are formed to extend in the direction perpendicular to the surface of the substrate 11, and are formed through the first insulating layer 17. The source 12 of the transistor 16 is electrically connected with one end of the first contact section 86, and the lower electrode layer 20 of the ferroelectric capacitor 100 is electrically connected with the other end of the first contact section 86. The drain 15 of the transistor 16 is electrically connected with one end of the second contact section 82, and a fourth contact section 78 described later is electrically connected with the other end of the second contact section 82.

The ferroelectric memory 1000 includes a second insulating layer 90 formed on the first insulating layer 17, a third contact section 74, a fourth contact section 78, and interconnects (or pads) 70 and 72. Contact holes 76 and 80 are formed in the second insulating layer 90. The contact hole 76 is formed through the first barrier film 50 and the second barrier film 60 on the ferroelectric capacitor 100. The contact hole 80 is formed through the second insulating layer 90 on the base 10. The third contact section 74 and the fourth contact section 78 having electric conductivity are formed in the contact holes 76 and 80, respectively. The upper electrode layer 40 of the ferroelectric capacitor 100 is electrically connected with one end of the third contact section 74, and the interconnect 70 is electrically connected with the other end of the third contact section 74. The transistor 16 and the interconnect 72 are electrically connected through the second contact section 82 and the fourth contact section 78.

The above-described embodiment illustrates the manufacturing process of a 1T1C ferroelectric memory having a stacked structure. However, the above-described method may also be applied to the manufacturing process of ferroelectric memories using various cell structures, such as a 1T1C ferroelectric memory having a planar structure, a 2T2C ferroelectric memory, and a simple matrix (cross-point) ferroelectric memory.

### 3. EXPERIMENTAL EXAMPLE

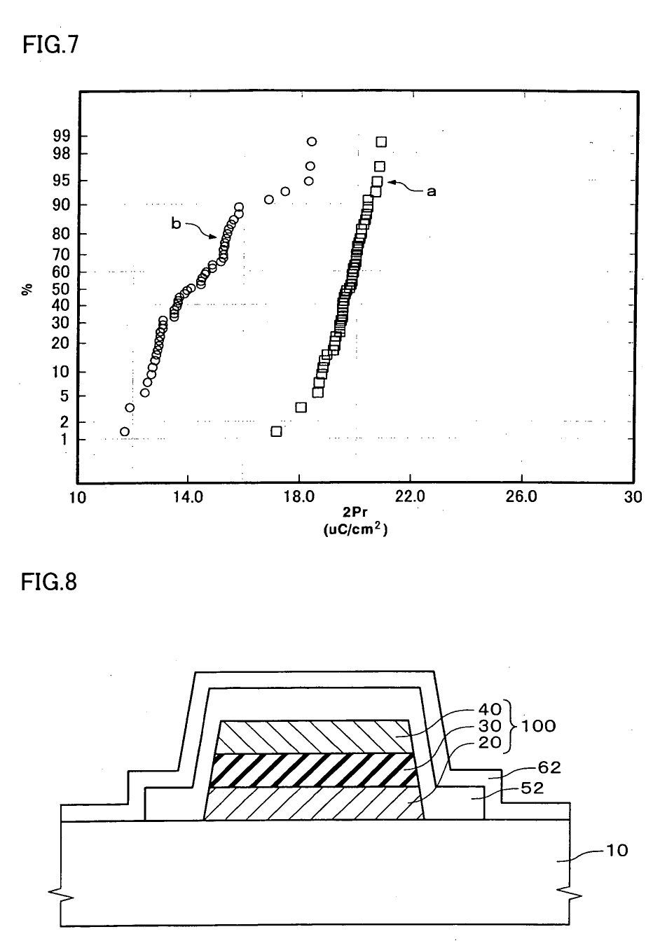

FIG. 7 is a graph showing the remanent polarization of the ferroelectric capacitor according to one embodiment of the invention and a variation of the remanent polarization in the base. The horizontal axis of the graph shown in FIG. 7 indicates the remanent polarization, and the vertical axis indicates the cumulative frequency of the remanent polarization. The value indicated by the symbol “a” indicates the characteristics of the ferroelectric memory according to the embodiment, and the value indicated by the symbol “b” indicates the characteristics of a related-art ferroelectric memory.

A sample of the ferroelectric memory used for the measurement is described below.

As the material for the lower electrode layer 20 and the upper electrode layer 40, a composite electrode having a multilayer structure of platinum, iridium oxide, and iridium was used. The thicknesses of the lower electrode layer 20 and the upper electrode layer 40 were 200 nm (upper and lower electrodes may differ in material thickness). As the material for the ferroelectric layer 30, PZTN was used. The thickness of the ferroelectric layer 30 was 150 nm. Aluminum oxide was used as the material for the first barrier film 50 and the second barrier film 60 of the ferroelectric memory according to one embodiment of the invention. The thickness of the first barrier film 50 was 40 nm, and the thickness of the second barrier film 60 was 20 nm. The size of the ferroelectric capacitor 100 was two microns square or less. The first barrier film 50 was formed by sputtering. As the sputtering conditions, the substrate temperature was set at room temperature, the RF power was set at 1.0 kW, and the oxygen/Ar flow rate ratio was set at 4%. The second barrier film 60 was formed by ALCVD. As the ALCVD conditions, the substrate temperature was set at 200 to 300° C. and the pressure was set at 1 torr. The following steps (3a) to (3d) were repeatedly performed.

(3a) Supply Ozone for 400 Ms as First Raw Material Molecule

(3b) Purge for 3200 ms

(3c) Supply Trimethylaluminum (TMA) for 100 Ms as Second Raw Material Molecule

(3d) Purge for 800 ms

In a comparative sample, a barrier film was formed by ALCVD. The thickness of the barrier film was 60 nm. The remaining configuration (e.g. material and thickness) of the comparative sample was the same as the configuration of the above sample.

The remanent polarization 2Pr of the above sample and the comparative sample was measured.

As shown in FIG. 7, it was confirmed that the ferroelectric memory according to one embodiment of the invention exhibits an improved remanent polarization 2Pr in comparison with the related-art ferroelectric memory and shows a small degree of variation in the remanent polarization 2Pr. Therefore, it was confirmed that the ferroelectric memory according to one embodiment of the invention deteriorates in characteristics to only a small extent during and after manufacture and exhibits high reliability.

It was also confirmed that the effects of the above-described embodiment become significant when the size of the ferroelectric capacitor 100 is reduced to two microns square or less.

### 4. Modification

The invention is not limited to the above-described embodiments. Various modifications and variations may be made within the scope of the invention. Modifications according to the invention are described below.

### 4.1 First Modification

FIG. 8 is a cross-sectional diagram schematically showing a capacitor section of a ferroelectric memory 2000 according to a first modification. The manufacturing process of the ferroelectric memory 2000 according to the first modification differs from the manufacturing process of the ferroelectric memory 1000 in that a first barrier film 52 is patterned into a specific shape after deposition and a second barrier film 62 is deposited thereafter.

As shown in FIG. 8, the first barrier film 52 is patterned by etching the first barrier film 52 in the region other than the region which covers the ferroelectric capacitor 100.

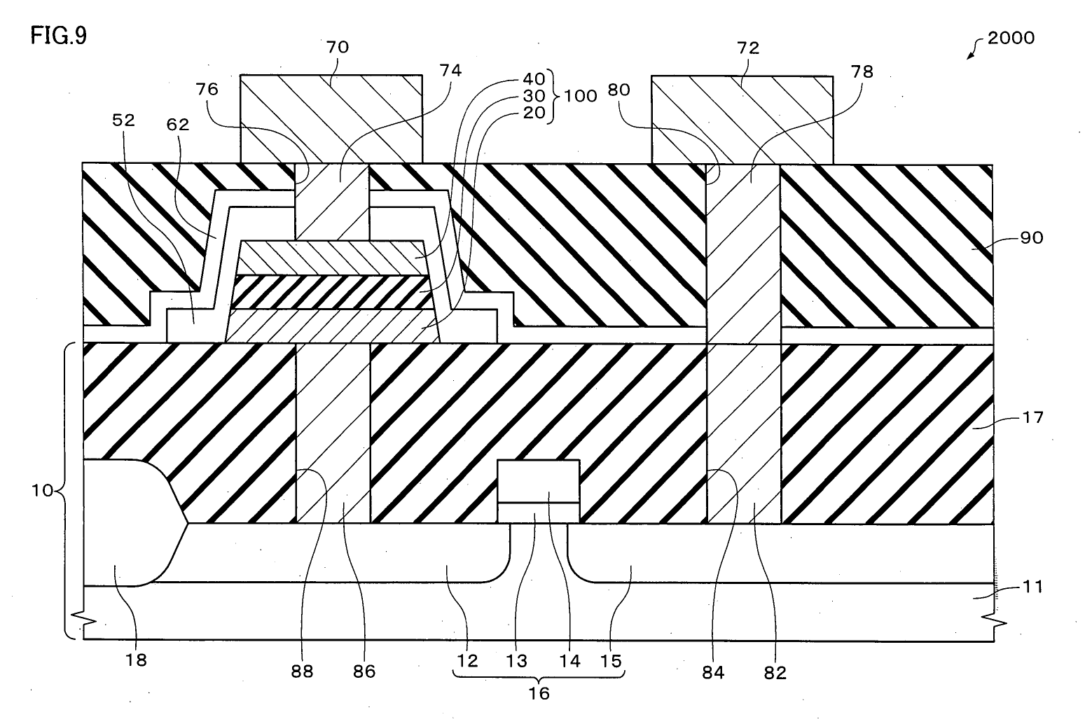

FIG. 9 is a cross-sectional diagram schematically showing the ferroelectric memory 2000 according to the first modification. As shown in FIG. 8, since the first barrier film 52 is patterned into a specific shape, only the second barrier film 62 remains on the base 10 in the region other than the region which covers the ferroelectric capacitor 100. Therefore, since the second barrier film 62 is shaped to cover the entire first barrier film 52, reducing agents can be prevented from entering the section formed when patterning the first barrier film 52, whereby the characteristics can be further improved.

### 4.2 Second Modification

### 4.2.1 Ferroelectric Memory According to Second Modification and Method of Manufacturing the Same

In a ferroelectric memory according to a second modification, the first barrier film may have oxygen supply capability. The first barrier film having oxygen supply capability may be formed by adding oxygen gas to the process gas used for sputtering in the above-described formation step of the first barrier film, for example. Since the process gas contains oxygen gas, oxygen is introduced into the first barrier film. As a result, the first barrier film can release the introduced oxygen during the heat treatment and supply the released oxygen to the ferroelectric capacitor 100. The process gas may contain argon gas or the like in addition to oxygen gas.

### 4.2.2 EXPERIMENTAL EXAMPLE

The amount of oxygen released from each barrier film was measured. In the experiment, a first barrier film formed by sputtering using the process gas to which oxygen gas was added in an amount of 5%, and a first barrier film formed without adding oxygen gas were used. The first barrier film was formed of an aluminum oxide film having a thickness of 40 nm. As the second barrier film, an aluminum oxide film formed by ALCVD and having a thickness of 20 nm was used.

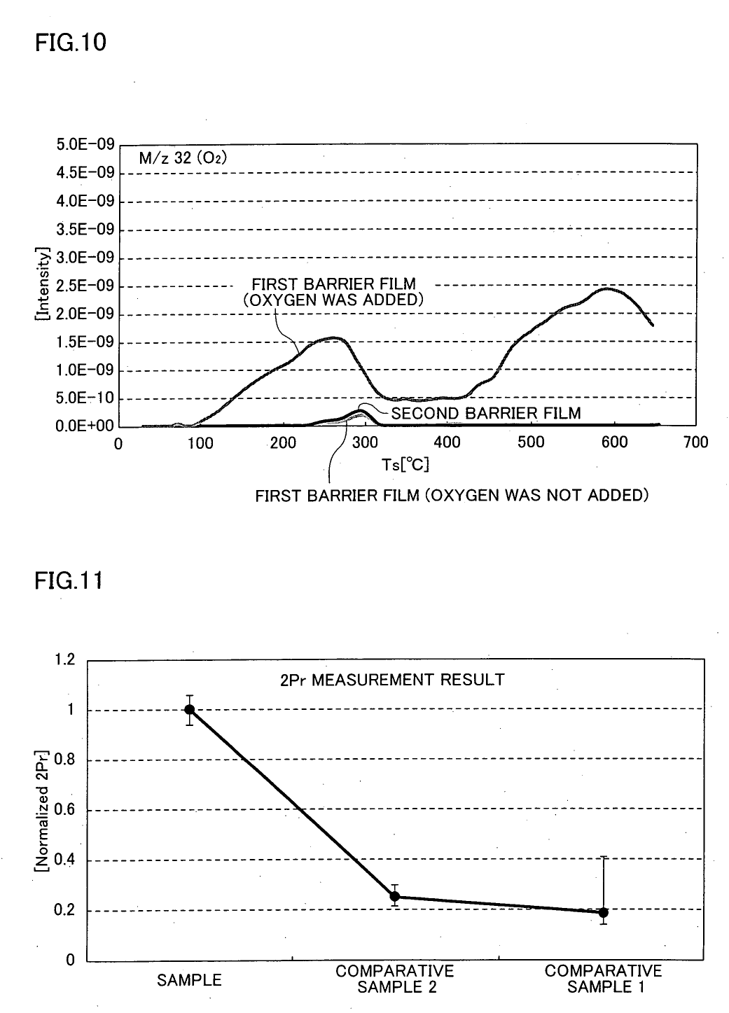

The barrier film was subjected to temperature-programmed desorption (TDS) analysis. The measurement results are shown in FIG. 10. As shown in FIG. 10, it was confirmed that the amount of oxygen released from the first barrier film to which oxygen was added was significantly greater than the amount of oxygen released from the other barrier films. It was also confirmed that the amount of oxygen released from the first barrier film to which oxygen was added was increased as the temperature became higher, and the amount of oxygen released from the first barrier film reached the maximum value at about 600° C. Therefore, since a large amount of oxygen is released from the first barrier film by performing the above-described heat treatment step after forming the first barrier film, damage (e.g. oxygen deficiency) to the ferroelectric capacitor 100 during manufacture can be reduced.

The remanent polarization 2Pr of the following sample and comparative samples was measured. As the sample, a sample formed by using the process gas to which oxygen gas was added in an amount of 5% was used. As the comparative samples, a sample formed without adding oxygen to the process gas (comparative sample 1) and a sample in which the first barrier film was not formed (i.e. only the second barrier film) (comparative sample 2) were used. The remaining experimental conditions were the same as the experimental conditions for “3. Experimental Example”. Therefore, further description is omitted.

FIG. 11 shows the measurement results for the remanent polarization 2Pr of the sample and the comparative samples. As shown in FIG. 11, it was confirmed that the remanent polarization 2Pr of the ferroelectric memory is improved by providing the first barrier film with the oxygen supply capability. Therefore, it was confirmed that the ferroelectric memory according to one embodiment of the invention deteriorates in characteristics to only a small extent during and after manufacture and exhibits high reliability.

### 4.3 Third Modification

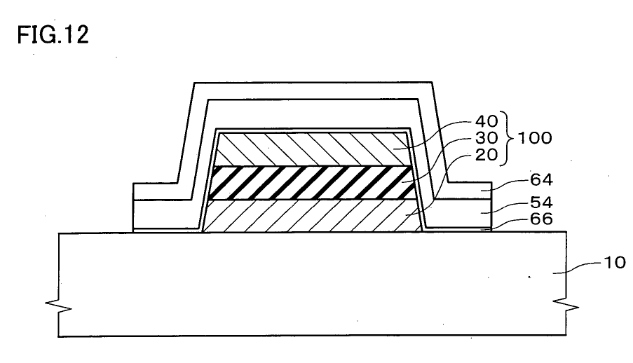

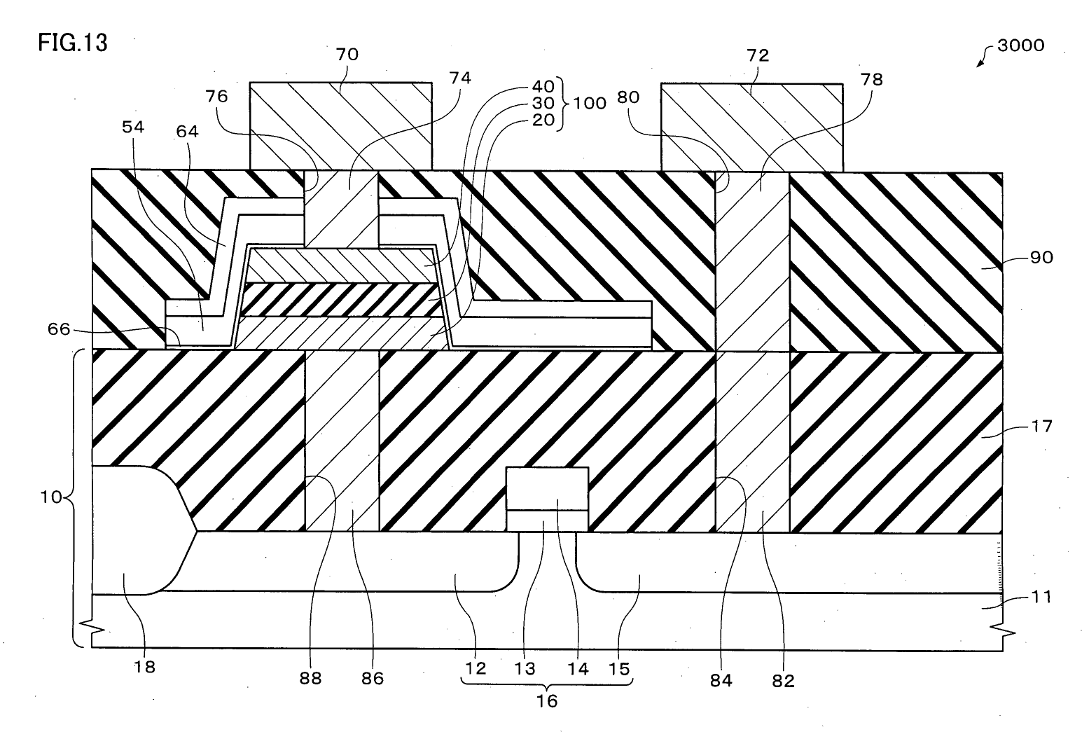

FIG. 12 is a cross-sectional diagram schematically showing a capacitor section of a ferroelectric memory 3000 according to a third modification, and FIG. 13 is a cross-sectional diagram schematically showing the ferroelectric memory 3000 according to the third modification. The ferroelectric memory 3000 according to the third modification differs from the ferroelectric memory 1000 in that the ferroelectric memory 3000 further includes a third barrier film 66.

The third barrier film 66 is formed between a first barrier film 54 and the ferroelectric capacitor 100. In other words, the third barrier film 66 is formed to cover the ferroelectric capacitor 100, and the first barrier film 54 is formed to cover the third barrier film 66. The third barrier film 66 is formed by chemical vapor deposition such as atomic layer chemical vapor deposition (ALCVD). This improves the adhesion between the third barrier film 66 and the ferroelectric capacitor 100.

The thickness of the third barrier film 66 is smaller than the thicknesses of the first barrier film 54 and the second barrier film 56. The thickness of the third barrier film 66 may be 5 nm or less, for example. Therefore, in the ferroelectric memory 3000 according to the third modification, when the first barrier film 54 has oxygen supply capability, oxygen supplied from the first barrier film 54 can pass through the third barrier film 66 toward the ferroelectric capacitor 100.

The third barrier film 66 has a density higher than the density of the first barrier film 54. This improves the adhesion between the third barrier film 66 and the ferroelectric capacitor 100.

A heat treatment may be performed in oxidation atmosphere comprising oxygen after forming at least one of the first barrier film 54, the second barrier film 56 and the third barrier film 66.

Preferred embodiments of the invention are described above. However, the invention is not limited to the above-described embodiments. The above embodiments illustrate the case where the number of barrier films is two or three. However, the number of barrier films may be four or more. It should be noted that various modifications and variations may be made in such a manner within the scope of the invention.

Although only some embodiments of the present invention have been described in detail above, those skilled in the art will readily appreciate that many modifications are possible in the embodiments without materially departing from the novel teachings and advantages of this invention. Accordingly, all such modifications are intended to be included within scope of this invention.

What is claimed is:

1. A method of manufacturing a ferroelectric memory, the method comprising:
(a) stacking a lower electrode layer, a ferroelectric layer, and an upper electrode layer on a base in that order to form a ferroelectric laminate;
(b) patterning the ferroelectric laminate to form a ferroelectric capacitor;
(c) forming a first barrier film which covers the ferroelectric capacitor by physical vapor deposition (PVD); and
(d) forming a second barrier film which covers the first barrier film by chemical vapor deposition (CVD).

2. The method of manufacturing a ferroelectric memory as defined in claim 1,
wherein the chemical vapor deposition is atomic layer chemical vapor deposition (ALCVD).

3. The method of manufacturing a ferroelectric memory as defined in claim 1,
wherein the physical vapor deposition is sputtering.

4. The method of manufacturing a ferroelectric memory as defined in claim 1,
wherein the step (c) includes patterning the first barrier film into a specific shape after depositing the first barrier film.

5. The method of manufacturing a ferroelectric memory as defined in claim 4,
wherein the second barrier film is deposited over the entire surface of the base.

6. The method of manufacturing a ferroelectric memory as defined in claim 1,
wherein the first barrier film and the second barrier film are nonconductive films.

7. The method of manufacturing a ferroelectric memory as defined in claim 6,
wherein the nonconductive film includes aluminum oxide or titanium oxide.

8. The method of manufacturing a ferroelectric memory as defined in claim 1, comprising:
forming a third barrier film which covers the ferroelectric capacitor by chemical vapor deposition between the steps (b) and (c),
wherein the step (c) includes forming the first barrier film which covers the third barrier film by physical vapor deposition.

9. The method of manufacturing a ferroelectric memory as defined in claim 1,
wherein the step (c) includes forming the first barrier film while supplying oxygen gas.

10. A ferroelectric memory, comprising:
a ferroelectric capacitor including a lower electrode layer, a ferroelectric layer, and an upper electrode layer formed on a base in that order; and
a plurality of barrier films covering the ferroelectric capacitor.

11. The ferroelectric memory as defined in claim 10, wherein the barrier films differ in density.

12. The ferroelectric memory as defined in claim 10,
wherein the barrier films include:
a first barrier film formed to cover the ferroelectric capacitor; and
a second barrier film formed to cover the first barrier film.

13. The ferroelectric memory as defined in claim 12,
wherein the first barrier film has a density lower than a density of the second barrier film.

14. The ferroelectric memory as defined in claim 12,
wherein the barrier films include a third barrier film formed to cover the ferroelectric capacitor, and
wherein the first barrier film is formed to cover the third barrier film.

15. The ferroelectric memory as defined in claim 14,
wherein the third barrier film has a thickness smaller than thicknesses of the first barrier film and the second barrier film.

16. The ferroelectric memory as defined in claim 14,
wherein the third barrier film has a density higher than a density of the first barrier film.

17. The ferroelectric memory as defined in claim 12,
wherein the first barrier film has oxygen supply capability.

18. The method of manufacturing a ferroelectric memory as defined in claim 8,
performing a heat treatment in oxidation atmosphere after forming at least one of the first barrier film, the second barrier film and the third barrier film.
